(19) United States
(12) Patent Application Publication
(10) Pub. No.: US 2026/0282873 A1
(43) Pub. Date: Sep. 17, 2026

(54) SEMICONDUCTOR STRUCTURE AND METHOD OF FORMATION

(71) Applicant: Taiwan Semiconductor Manufacturing Company, Ltd., Hsinchu (TW)

(72) Inventors: Hung-Chang Sun, Kaohsiung City (TW); Chung-Te Lin, Tainan City (TW); Katherine H. Chiang, New Taipei City (TW); Pin-Cheng Hsu, Zhubei City (TW); Chen-Jun Wu, Hsinchu City (TW); Chieh-Fang Chen, Hsinchu County (TW)

(21) Appl. No.: 19/254,198

(22) Filed: Jun. 30, 2025

Related U.S. Application Data
(60) Provisional application No. 63/769,855, filed on Mar. 11, 2025.

(51) Int. Cl. H01L 23/522; H01L 21/768; H01L 23/00; H01L 23/528

(52) U.S. Cl. CPC H10W 20/42; H10W 20/033; H10W 20/056; H10W 20/082; H10W 20/089; H10W 20/435; H10W 72/923

(57) ABSTRACT

The present disclosure, in some embodiments, relates to an integrated chip. The integrated chip includes a lower interconnect layer disposed within a lower inter-level dielectric (ILD) layer on a substrate, and an upper interconnect layer disposed within an upper ILD layer on the substrate. One or more intermediate ILD layers are disposed vertically between the lower ILD layer and the upper ILD layer. One or more intermediate interconnect layers are disposed within the one or more intermediate ILD layers. A via vertically extends between the lower interconnect layer and the upper interconnect layer. The via laterally contacts one or more sidewalls of the one or more intermediate interconnect layers.

### REFERENCE TO RELATED APPLICATION

This Application claims the benefit of U.S. Provisional Application No. 63/769,855, filed on Mar. 11, 2025, the contents of which are incorporated herein by reference in their entirety.

### BACKGROUND

Modern-day integrated chips comprise millions or billions of semiconductor devices formed on a semiconductor substrate (e.g., a silicon substrate). The semiconductor devices are electrically coupled together by interconnects. The interconnects comprise interconnect wires and interconnect vias disposed within a dielectric structure over a semiconductor substrate. By using interconnects to electrically couple the semiconductor devices together, the semiconductor devices are able to perform logical functions that enable operation of an integrated chip.

### BRIEF DESCRIPTION OF THE DRAWINGS

Aspects of the present disclosure are best understood from the following detailed description when read with the accompanying figures. The figures are drawn to clearly illustrate relevant aspects of the embodiments. The figures may illustrate relationships between various structures and/or elements within the embodiments. It is noted that the figures are not necessarily drawn to scale. In some instances, the dimensions of the various features may be arbitrarily increased or reduced for clarity of discussion.

FIG. 1 illustrates a cross-sectional view of some embodiments of an integrated chip structure having a via extending over multiple interconnect layers.

FIG. 2 illustrates a cross-sectional view of some additional embodiments of an integrated chip structure having a via extending over multiple interconnect layers.

FIGS. 3A-3C illustrate top-views of various embodiments of an integrated chip structure having a via extending over multiple interconnect layers.

FIG. 4 illustrates a cross-sectional view of some additional embodiments of an integrated chip structure having a via extending over multiple interconnect layers.

FIGS. 5A-5B illustrate some additional embodiments of an integrated chip structure having a via extending over multiple interconnect layers.

FIG. 6 illustrates a cross-sectional view of some additional embodiments of an integrated chip structure having a via extending over multiple interconnect layers.

FIG. 7 illustrates a cross-sectional view of some additional embodiments of an integrated chip structure having a via extending over multiple interconnect layers.

FIG. 8 illustrates a cross-sectional view of some additional embodiments of an integrated chip structure having a via extending over multiple interconnect layers.

FIG. 9 illustrates a cross-sectional view of some additional embodiments of an integrated chip structure having a via extending over multiple interconnect layers.

FIGS. 10A-10F illustrate some additional embodiments of an integrated chip structure having a via extending over multiple interconnect layers.

FIGS. 11-19 illustrate cross-sectional views of some embodiments to a method of forming an integrated chip structure having a via extending over multiple interconnect layers.

FIGS. 20-29 illustrate cross-sectional views of some additional embodiments to a method of forming an integrated chip structure having a via extending over multiple interconnect layers.

FIG. 30 illustrates a flow diagram of some embodiments of a method of forming an integrated chip structure having a via extending over multiple interconnect layers.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In some embodiments, the terms “approximately” and/or “about” can be interpreted as meaning +/−10% or +/−5%, while in other embodiments, the terms “approximately” and/or “about” can be interpreted as meaning within the normal fabrication tolerances of a given fab manufacturing flow.

Integrated chip structures include conductive interconnects disposed over a substrate. The conductive interconnects comprise alternating layers of conductive vias and conductive wires that increase in size as a distance over the substrate increases. The conductive wires are configured to provide for lateral routing, while the conductive vias are configured to provide for vertical routing between adjacent conductive wires. For example, a first conductive via may provide for vertical routing between an underlying conductive wire and an overlying conductive wire. The conductive interconnects are often formed using a damascene process (e.g., a single damascene process or a dual damascene process). The damascene process is performed by forming an ILD layer over the substrate, etching the ILD layer to form a hole and/or a trench, and filling the hole and/or trench with a conductive material.

The use of damascene processes to form conductive interconnects requires different masks for each of the interconnect wire and interconnect via layers. Furthermore, in single damascene processes planarization processes (e.g., CMP processes) are used during the formation of each interconnect wire and interconnect via layer. The lithography and CMP processes used to form interconnect layers are expensive and time consuming. Back-end-of-line (BEOL) interconnect stacks with many interconnect layers may use a large number of masks and/or CMP processes, thereby limiting throughput (e.g., limiting wafers per hour) and leading to high integrated chip production costs.

The present disclosure relates to a method of forming an integrated chip structure comprising a via that vertically extends through an intermediate interconnect to electrically couple an underlying lower interconnect to an overlying upper interconnect. In some embodiments, the method includes forming a lower interconnect within a lower ILD layer formed on a substrate. One or more intermediate interconnects are subsequently formed within one or more intermediate ILD layers formed over the lower ILD layer. The one or more intermediate ILD layers are patterned to form an opening extending through the one or more intermediate ILD layers. An etchant is introduced into the opening to laterally etch the one or more intermediate ILD layers and form a via opening, which exposes an upper surface of the lower interconnect and a sidewall of the one or more intermediate interconnects. A via is formed within the via opening and an upper interconnect is formed over the via. By forming the via to extend between the lower interconnect and the upper interconnect, a single fabrication process may be used to connect multiple interconnect layers, thereby reducing a cost (e.g., by using less lithography and CMP processes) and increasing a throughput of integrated chip fabrication.

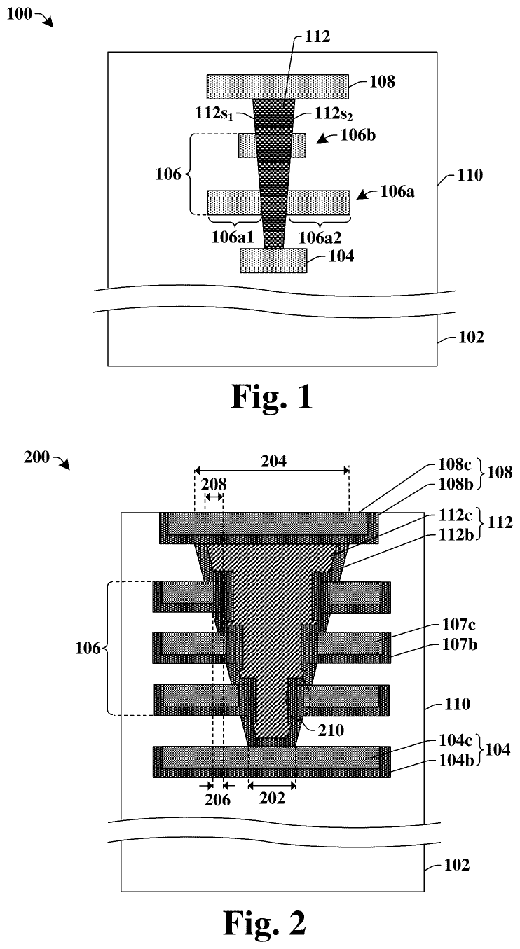

FIG. 1 illustrates a cross-sectional view of some embodiments of an integrated chip structure 100 having a via extending over multiple interconnect layers.

The integrated chip structure 100 comprises an inter-level dielectric (ILD) structure 110 disposed over a substrate 102. The ILD structure 110 includes a plurality of different ILD layers stacked onto one another. A lower interconnect layer 104 (e.g., lower tier metal) and an upper interconnect layer 108 (e.g., upper tier metal) are disposed within the ILD structure 110. The lower interconnect layer 104 comprises one or more lower interconnects (e.g., lower tier metal patterns) and the upper interconnect layer 108 comprises one or more upper interconnects (e.g., upper tier metal patterns). One or more intermediate interconnect layers 106 (e.g., intermediate tier metals) are disposed within the ILD structure 110 vertically between the lower interconnect layer 104 and the upper interconnect layer 108. The one or more intermediate interconnect layers 106 respectively comprise one or more intermediate interconnects (e.g., intermediate tier metal patterns). In some embodiments, the lower interconnect layer 104, the one or more intermediate interconnect layers 106, and the upper interconnect layer 108 comprise interconnect wires that are configured to laterally extend over the substrate 102.

In some embodiments, the one or more intermediate interconnect layers 106 comprise a first intermediate interconnect layer 106a and a second intermediate interconnect layer 106b over the first intermediate interconnect layer 106a. In some embodiments, the one or more intermediate interconnect layers 106 may respectively comprise intermediate interconnect segments that are laterally separated from one another in a cross-sectional view. For example, the first intermediate interconnect layer 106a may comprise a first intermediate interconnect segment 106a1 and a second intermediate interconnect segment 106a2.

A via 112, also known herein as a deep via or a protracted via, is disposed within the ILD structure 110. The via 112 vertically extends between the lower interconnect layer 104 and the upper interconnect layer 108. The via 112 laterally contacts one or more sidewalls of the one or more intermediate interconnect layers 106. For example, the via 112 may comprise a first outer sidewall 112s₁ that contacts a sidewall of the one or more intermediate interconnect layers 106. In some embodiments, the via 112 laterally extends between sidewalls of the one or more intermediate interconnect segments, 106a1 and 106a2, that face one another. In some embodiments, the first outer sidewall 112s₁ of the via 112 may laterally contact a first sidewall of the first intermediate interconnect segment 106a1 and a second outer sidewall 112s₂ of the via 112 may laterally contact a second sidewall of the second intermediate interconnect segment 106a2.

By having the via 112 contact the lower interconnect layer 104 below the one or more intermediate interconnect layers 106 and the upper interconnect layer 108 above the one or more intermediate interconnect layers 106, the via 112 is able to electrically couple at least three different interconnect layers (e.g., interconnect wire layers). By having the via 112 electrically couple at least three different interconnect layers, the via 112 is able to reduce a cost associated with forming an interconnect stack (e.g., a back-end-of-line interconnect stack). This is because a single lithography process and a single CMP process can be used to form the via 112, rather than using multiple lithography and CMP processes to form multiple vias. This also improves a throughput of a fabrication process since lithography and CMP processes can be time consuming.

FIG. 2 illustrates a cross-sectional view of some additional embodiments of an integrated chip structure 200 having a via extending over multiple interconnect layers.

The integrated chip structure 200 comprises an inter-level dielectric (ILD) structure 110 disposed over a substrate 102. The ILD structure 110 includes a plurality of different ILD layers stacked onto one another. In some embodiments, the plurality of different ILD layers may comprise one or more of silicon dioxide, carbon doped silicon oxide (SiCOH), phosphosilicate glass (PSG), borophosphosilicate glass (BPSG), borosilicate glass (BSG), fluorosilicate glass (FSG), undoped silicate glass (USG), and/or the like.

A lower interconnect layer 104 is disposed within the ILD structure 110. The lower interconnect layer comprises one or more lower interconnects respectively including a lower barrier 104b and a lower conductive core 104c. The lower barrier 104b extends along sidewalls and a lower surface of the lower conductive core 104c. In some embodiments, the lower conductive core 104c may comprise tungsten, copper, aluminum, and/or the like. In some embodiments, the lower barrier 104b may comprise titanium nitride, tantalum nitride, tungsten-titanium, and/or the like.

One or more intermediate interconnect layers 106 are disposed within the ILD structure 110 above the lower interconnect layer 104. In some embodiments, the one or more intermediate interconnect layers 106 may comprise a first intermediate interconnect layer 106a, a second intermediate interconnect layer 106b over the first intermediate interconnect layer 106a, and a third intermediate interconnect layer 106c over the second intermediate interconnect layer 106b. The one or more intermediate interconnect layers 106 comprise one or more intermediate interconnects respectively comprising an intermediate barrier 107b and an intermediate conductive core 107c. The intermediate barrier 107b extends along sidewalls and a lower surface of the intermediate conductive core 107c. In some embodiments, the intermediate conductive core 107c may comprise tungsten, copper, aluminum, and/or the like. In some embodiments, the intermediate barrier 107b may comprise titanium nitride, tantalum nitride, tungsten-titanium, and/or the like. In some embodiments, one or more of the one or more intermediate interconnect layers 106 may comprise intermediate interconnect segments that are laterally separated from one another in a cross-sectional view.

An upper interconnect layer 108 is disposed within the ILD structure 110 above the one or more intermediate interconnect layers 106. The upper interconnect layer 108 comprises one or more upper interconnects respectively including an upper barrier 108b and an upper conductive core 108c. The upper barrier 108b extends along sidewalls and a lower surface of the upper conductive core 108c. In some embodiments, the upper conductive core 108c may comprise tungsten, copper, aluminum, and/or the like. In some embodiments, the upper barrier 108b may comprise titanium nitride, tantalum nitride, tungsten-titanium, and/or the like.

A via 112 is disposed within the ILD structure 110. The via 112 vertically extends between the lower interconnect layer 104 and the upper interconnect layer 108. The via 112 comprises a via barrier 112b and a via conductive core 112c. The via barrier 112b extends along sidewalls and a lower surface of the via conductive core 112c. In some embodiments, the via conductive core 112c may comprise tungsten, copper, aluminum, and/or the like. In some embodiments, the via barrier 112b may comprise titanium nitride, tantalum nitride, tungsten-titanium, and/or the like. In some embodiments, the via 112 may have angled outermost sidewalls that give the via 112 a tapered width that increases from a first width 202 along a bottommost surface to a larger second width 204 along a topmost surface. In some embodiments, the second width 204 may be substantially equal to that a width of an interconnect (measured along a minimum lateral distance of the interconnect) on the lower interconnect layer 104, the one or more intermediate interconnect layers 106, and/or the like upper interconnect layer 108.

The via 112 vertically contacts the lower interconnect layer 104 and the upper interconnect layer 108. The via 112 also laterally contacts one or more sidewalls of the one or more intermediate interconnect layers 106. In some embodiments, the via barrier 112b contacts the intermediate barrier 107b along an interface. In some embodiments, the first distance 206 may be different than (e.g., smaller than) the second distance 208. In some embodiments, the via 112 both laterally and vertically contacts the one or more intermediate interconnect layers 106. In some embodiments, the via 112 wraps around an upper surface and a lower surface of the one or more intermediate interconnect layers 106. For example, the via 112 may extend for a first distance 206 along a lower surface of a first intermediate interconnect layer 106a and may extend for a second distance 208 along an upper surface of the first intermediate interconnect layer 106a.

In some embodiments, the via 112 may have recesses 210 arranged along opposing sides of the via 112. The one or more intermediate interconnect layers 106 may be partially embedded within the recesses 210. The one or more intermediate interconnect layers 106 protrude outward from within the recesses 210 to laterally outside of the via 112. In some embodiments, the via 112 comprises a protrusion laterally extending outward from a sidewall of the via 112 to directly between the first intermediate interconnect layer 106a and the second intermediate interconnect layer 106b.

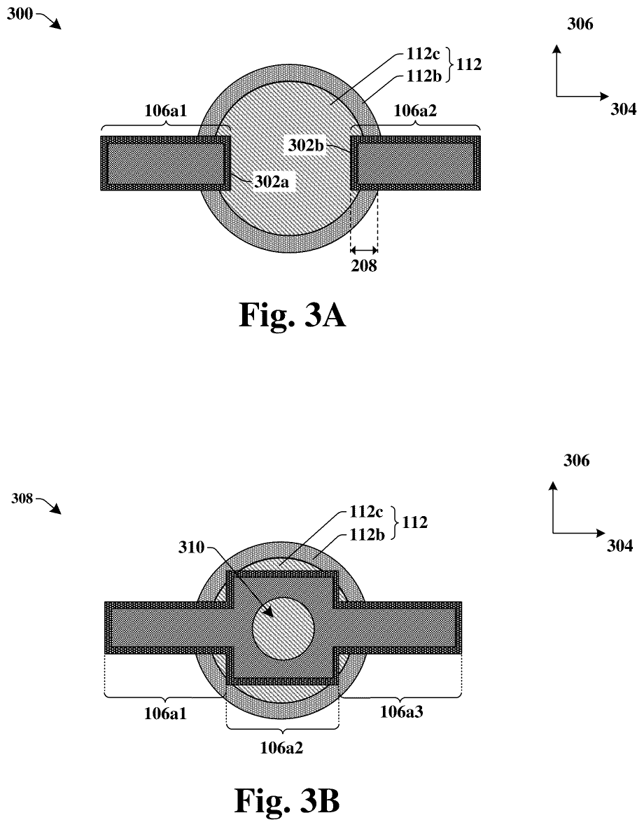

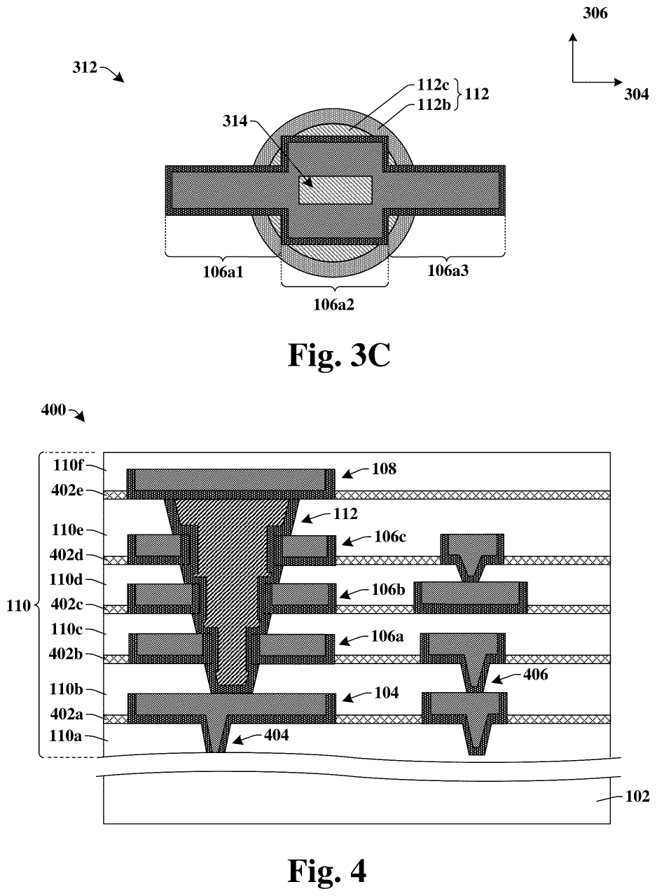

FIGS. 3A-3C illustrate top-views of various embodiments of an integrated chip structure having a via extending over multiple interconnect layers.

FIG. 3A illustrates a top-view 300 of some embodiments of an intermediate interconnect layer and a via.

Top-view 300 illustrates a first intermediate interconnect layer comprising a first intermediate interconnect segment 106a1 and a second intermediate interconnect segment 106a2. The first intermediate interconnect segment 106a1 and the second intermediate interconnect segment 106a2 comprise interconnects disposed on opposing sides of the via 112. The first intermediate interconnect segment 106a1 and the second intermediate interconnect segment 106a2 have outermost sidewalls, 302a and 302b, which face one another and that are separated from one another along a first direction 304 by the via 112. In some embodiments, the first intermediate interconnect segment 106a1 contacts a first sidewall of the via 112 and the second intermediate interconnect segment 106a2 contacts an opposing second sidewall of the via 112. The via 112 laterally extends in a second direction 306 past opposing edges of the outermost sidewalls, 302a and 302b. The second direction 306 is perpendicular to the first direction 304.

FIG. 3B illustrates a top-view 308 of some additional embodiments of an intermediate interconnect layer and a via.

Top-view 308 illustrates a first intermediate interconnect layer comprising a first intermediate interconnect having a first intermediate interconnect segment 106a1, a second intermediate interconnect segment 106a2, and a third intermediate interconnect segment 106a3. The first intermediate interconnect segment 106a1 and the third intermediate interconnect segment 106a3 are arranged on opposing sides of the second intermediate interconnect segment 106a2. The first intermediate interconnect segment 106a1 and the third intermediate interconnect segment 106a3 have smaller widths than the second intermediate interconnect segment 106a2. The second intermediate interconnect segment 106a2 has an interior sidewall that forms an elliptical shaped aperture 310 (e.g., an oval or circular shaped aperture) extending through the first intermediate interconnect. A via 112 extends through the elliptical shaped aperture 310, such that the first intermediate interconnect wraps around a part of the via 112 in a closed and unbroken loop.

FIG. 3C illustrates a top-view 312 of some alternative embodiments of an intermediate interconnect layer and a via.

Top-view 312 illustrates a first intermediate interconnect layer comprising a first intermediate interconnect having a first intermediate interconnect segment 106a1, a second intermediate interconnect segment 106a2, and a third intermediate interconnect segment 106a3. The third intermediate interconnect segment 106a3 has an interior sidewall that forms a rectangular shaped aperture 314 extending through the first intermediate interconnect. A via 112 extends through the rectangular shaped aperture 314, such that the first intermediate interconnect wraps around a part of the via 112 in a closed and unbroken loop.

FIG. 4 illustrates a cross-sectional view of some additional embodiments of an integrated chip structure 400 having a via extending over multiple interconnect layers.

The integrated chip structure 400 comprises an ILD structure 110 disposed over a substrate 102. The ILD structure 110 includes a plurality of different ILD layers 110a-110f stacked onto one another. In some embodiments, the plurality of different ILD layers 110a-110f include one or more lower ILD layers 110a-110b, one or more intermediate ILD layers 110c-110e over the lower ILD layer 110b, and an upper ILD layer 110f over the one or more intermediate ILD layers 110c-110f. In some embodiments, the plurality of different ILD layers 110a-110e are vertically separated from one another by a plurality of etch stop layers (ESL) 402a-402e. The plurality of ESL 402a-402e may include a lower ESL 402a, one or more intermediate ESL 402b-402d, and an upper ESL 402e. A lower interconnect layer 104 is disposed within lower ILD layer 110b, one or more intermediate interconnect layers 106 are disposed within the one or more intermediate ILD layers 110c-110e, and an upper interconnect layer 108 is disposed within the upper ILD layer 110f.

A via 112 is disposed within the ILD structure 110. The via 112 vertically extends through the one or more intermediate ILD layers 110c-110e and the one or more intermediate ESL 402b-402d, to electrically couple the lower interconnect layer 104 and the upper interconnect layer 108. In some embodiments, a lower via 404 may be disposed below the lower interconnect layer 104. In some embodiments, the via 112 has a larger width than the lower via 404. In other embodiments (not shown), the via 112 has a width that is substantially equal to the lower via 404.

In some embodiments, the integrated chip structure 400 may further comprise one or more additional vias 406 arranged within the ILD structure 110 and laterally separated from the via 112 by the ILD structure. The via 112 may vertically extend past one or more of the one or more additional vias 406.

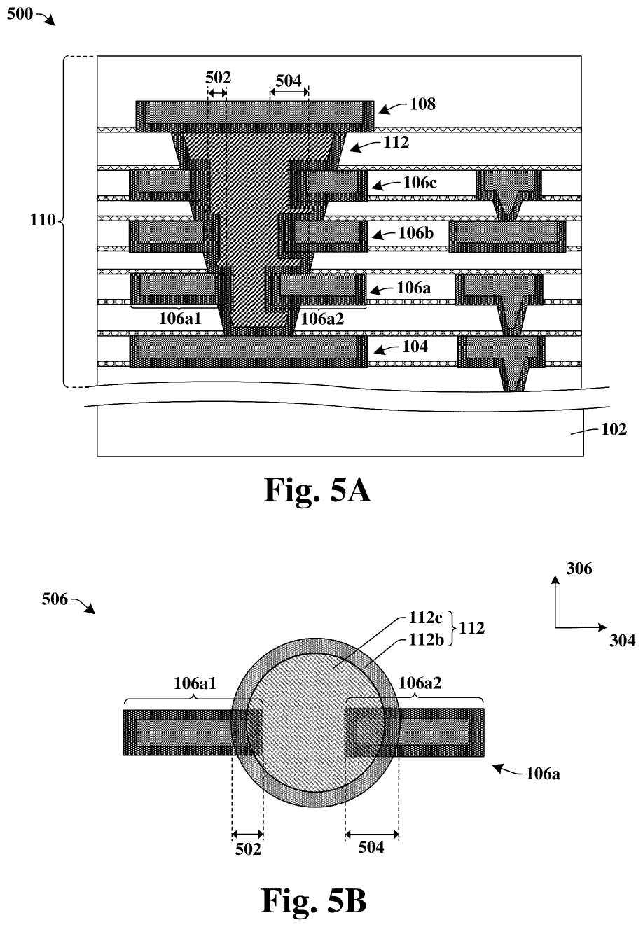

FIG. 5A illustrates a cross-sectional view of some additional embodiments of an integrated chip structure 500 having a via extending over multiple interconnect layers.

The integrated chip structure 500 comprises an ILD structure 110 disposed over a substrate 102. The ILD structure comprises a plurality of ILD layers interleaved between neighboring ESLs. A lower interconnect layer 104 and an upper interconnect layer 108 are disposed within the ILD structure 110. One or more intermediate interconnect layers 106a-106c are disposed within the ILD structure 110 vertically between the lower interconnect layer 104 and the upper interconnect layer 108. The one or more intermediate interconnect layers 106a-106c comprise a first intermediate interconnect layer 106a having a first intermediate interconnect segment 106a1 and a second intermediate interconnect segment 106a2.

A via 112 is disposed within the ILD structure 110. The via 112 vertically extends between the lower interconnect layer 104 and the upper interconnect layer 108. The via 112 laterally overlaps the first intermediate interconnect segment 106a1 by a first non-zero distance 502 and the second intermediate interconnect segment 106a2 by a second non-zero distance 504. The via 112 is laterally off-centered from the first intermediate interconnect segment 106a1 and the second intermediate interconnect segment 106a2, such that the first non-zero distance 502 is larger than the second non-zero distance 504. Since the via 112 laterally overlaps the first intermediate interconnect segment 106a1 and the second intermediate interconnect segment 106a2, the via 112 is able to make good electrical contact with the first intermediate interconnect segment 106a1 and the second intermediate interconnect segment 106a2 despite the via 112 being laterally off-centered.

FIG. 5B illustrates a top-view 506 of some additional embodiments of an integrated chip structure having a via extending over multiple interconnect layers.

Top-view 506 illustrates a first intermediate interconnect layer 106a having a first intermediate interconnect segment 106a1 and a second intermediate interconnect segment 106a2 arranged on opposing sides of the via 112. The first intermediate interconnect segment 106a1 and the second intermediate interconnect segment 106a2 have outermost sidewalls that face one another and that are separated from one another by the via 112. The first intermediate interconnect segment 106a1 contacts a first sidewall of the via 112 and the second intermediate interconnect segment 106a2 contacts an opposing second sidewall of the via 112.

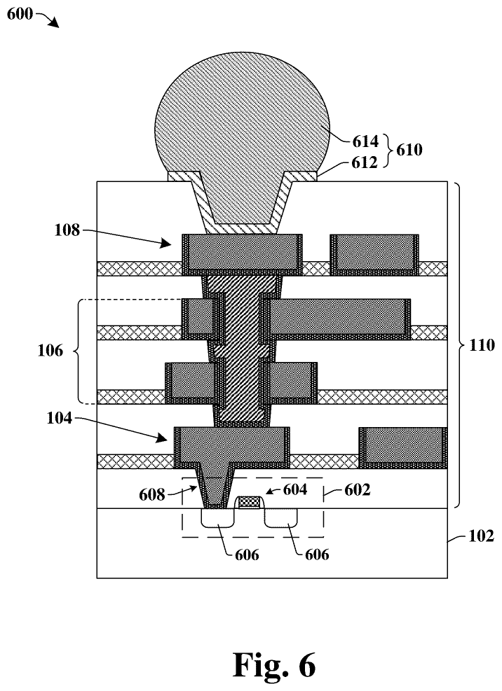

FIG. 6 illustrates a cross-sectional view of some additional embodiments of an integrated chip structure 600 having a via extending over multiple interconnect layers.

The integrated chip structure 600 comprises a semiconductor device 602 disposed within a substrate 102. In some embodiments, the semiconductor device 602 may comprise a transistor device (e.g., a planar FET, a Fin-FET, a gate all around FET, a complimentary FET (C-FET), and/or the like). In some embodiments, the transistor device may comprise a gate structure 604 disposed over a channel region arranged between source/drain regions 606.

The semiconductor device 602 is coupled to a lower interconnect layer 104 by way of a lower via 608 disposed within an ILD structure 110 overlying the substrate 102. In some embodiments, the lower via 608 may comprise a conductive contact physically contacting one of the source/drain regions 606 of the transistor device. The lower via 608 has a first width. A via 112 is arranged over the lower interconnect layer 104. The via 112 vertically extends past one or more intermediate interconnect layers 106 to contact an upper interconnect layer 108 that is directly over the lower interconnect layer 104. The via 112 has a second width that is larger than the first width. The larger width of the via 112 allows for the via to provide for a relatively low resistance contact between the lower interconnect layer 104 and the upper interconnect layer 108.

The upper interconnect layer 108 is further coupled to a bonding structure 610. In some embodiments, the bonding structure 610 may comprise an under bump metallization (UBM) structure 612 and an overlying conductive bump structure 614. In some embodiments, the conductive bump structure 614 may comprise a solder bump. In other embodiments, the bonding structure 610 may alternatively and/or additionally comprise a redistribution structure, a bond pad, and/or the like.

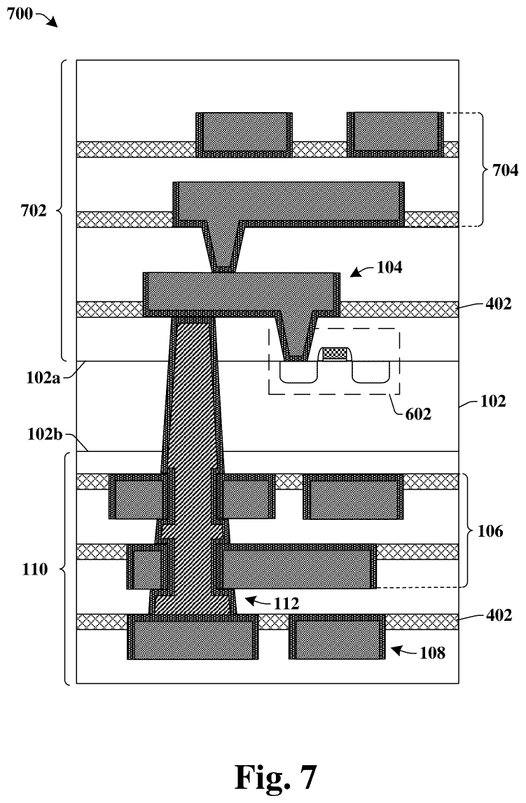

FIG. 7 illustrates a cross-sectional view of some additional embodiments of an integrated chip structure 700 having a via extending over multiple interconnect layers.

The integrated chip structure 700 includes a semiconductor device 602 arranged along a first side 102a of a substrate 102. In some embodiments, the semiconductor device 602 comprises a transistor device.

A front-side ILD structure 702 is arranged along the first side 102a (e.g., a front-side) of the substrate 102. The front-side ILD structure 702 may comprise a plurality of ILD layers stacked onto one another. A plurality of front-side interconnect layers 704 are disposed within the front-side ILD structure 702. In some embodiments, the plurality of front-side interconnect layers 704 may comprise front-side interconnects including conductive contacts, interconnect wires, interconnect vias, and/or the like. In some embodiments, the front-side ILD structure 702 may also surround a lower interconnect layer 104 that is within a lower ILD layer within the front-side ILD structure 702. In some embodiments, the front-side ILD structure 702 may comprise etch stop layers 402 between neighboring ILD layers.

An ILD structure 110 is arranged along a second side 102b (e.g., a back-side) of the substrate 102 opposing the first side 102a of the substrate 102. The ILD structure 110 surrounds a plurality of interconnect layers 106-108 including one or more intermediate interconnect layers 106 and an upper interconnect layer 108. The ILD structure 110 also surrounds a via 112, which extends between the lower interconnect layer 104 and the upper interconnect layer 108. The via 112 vertically extends from within the ILD structure 110, through the substrate 102 and into the front-side ILD structure 702. In some embodiments, the ILD structure 110 may comprise etch stop layers 402 between neighboring ILD layers. In other embodiments, the ILD structure 110 may omit etch stop layers, so that neighboring ILD layers contact one another.

In some embodiments, the plurality of interconnect layers 106-108 are configured to deliver power from a package to the semiconductor device 602. For example, the upper interconnect layer 108 may comprise a power rail configured to deliver power (e.g., VDD, VSS, etc.) and/or ground signals. Delivering power to the semiconductor device 602 using the plurality of interconnect layers 106-108 on the second side 102b of the substrate 102 frees space on the first side 102a of the substrate 102 for electrical routing between semiconductor devices. Furthermore, it may enable power delivery to the semiconductor device 602 through wider, less resistive metal lines, without electrons needing to travel through a complex BEOL stack. This may benefit IR drop, improve power delivery performance, reduce routing congestion in the BEOL, and/or the like.

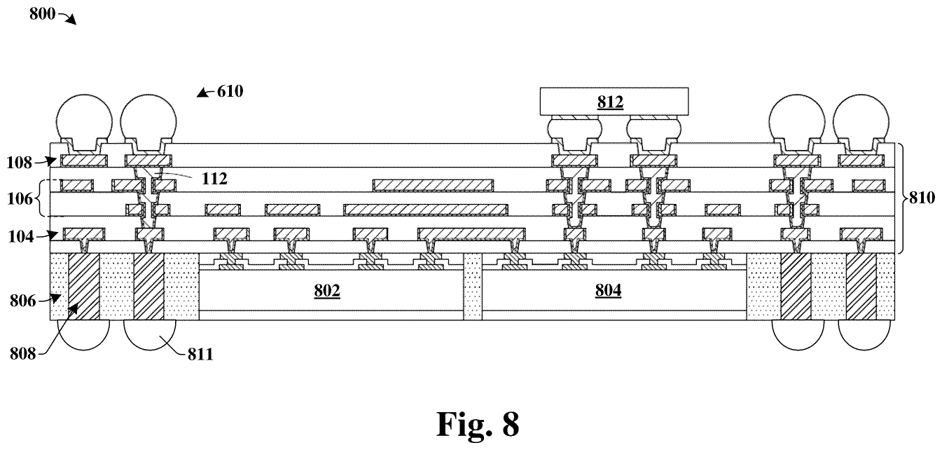

FIG. 8 illustrates a cross-sectional view of some additional embodiments of an integrated chip structure 800 having a via extending over multiple interconnect layers.

The integrated chip structure 800 comprises a plurality of chiplets 802-804 laterally surrounded by a molding compound 806. In various embodiments, the molding compound 806 may comprise a polymer, a thermosetting plastic, a resin, and/or the like. The molding compound 806 may laterally separate the plurality of chiplets 802-804 from one another and from one or more conductive pillars 808 extending through the molding compound 806. The plurality of chiplets 802-804 are electrically coupled to a redistribution structure 810 disposed over the molding compound 806 by way of back-end-of-line (BEOL) interconnect structures surrounded by the molding compound 806. In some embodiments, the plurality of chiplets 802-804 and the molding compound 806 may be disposed over an underlying carrier substrate or interposer substrate (not shown). In some embodiments, the one or more conductive pillars 808 may be coupled to the underlying carrier substrate or interposer substrate by way of one or more conductive bumps 811 (e.g., microbumps).

The redistribution structure 810 comprises a plurality of conductive redistribution interconnects that electrically couple the plurality of chiplets 802-804 to one another, to the conductive pillars 808, to one or more additional chiplets 812, and/or a bonding structure 610. In some embodiments, the conductive redistribution interconnects include a lower interconnect layer 104, one or more intermediate interconnect layers 106, and an upper interconnect layer 108. The conductive redistribution interconnects may also comprise a via 112 extending over multiple ones of the plurality of conductive redistribution interconnects. The via 112 enables the redistribution structure 810 to be formed at a lower cost and with higher throughput.

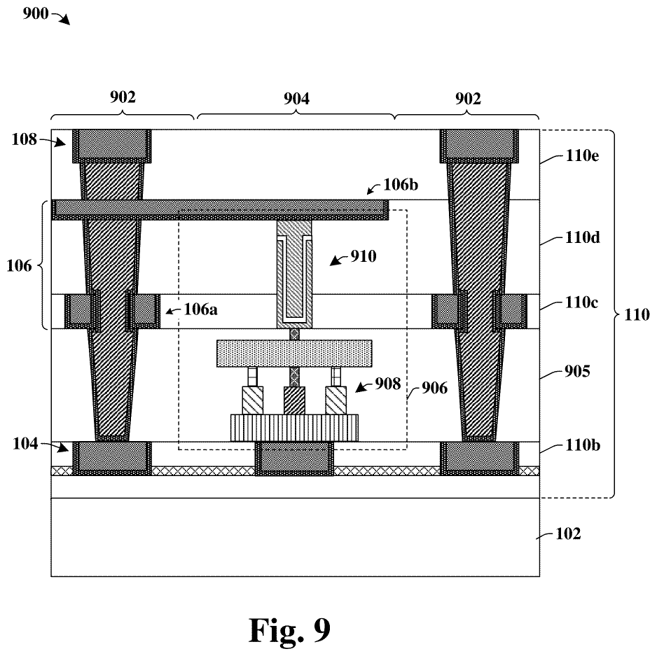

FIG. 9 illustrates a cross-sectional view of some additional embodiments of an integrated chip structure 900 having a via extending over multiple interconnect layers.

The integrated chip structure 900 includes a substrate 102 having a logic region 902 and a memory region 904. An ILD structure 110 is disposed over the substrate 102 within the logic region 902 and the memory region 904. Within the logic region 902, the ILD structure 110 surrounds a plurality of interconnect layers including a lower interconnect layer 104, one or more intermediate interconnect layers 106, and an upper interconnect layer 108. Within the memory region 804, the ILD structure 110 further surrounds a plurality of memory devices 906.

The plurality of memory devices 906 include a plurality of transistor devices 908 respectively coupled to a data storage element 910 configured to store a first data state (e.g., a logical ‘0’) or a second data state (e.g., a logical ‘1’). In some embodiments, the data storage element 910 may comprise a capacitor. In other embodiments, the data storage element 910 may comprise a resistive random access memory device (RRAM), a ferroelectric random access memory (FeRAM) device, a magneto resistive random access memory (MRAM) device, a phase change random access memory (PCRAM) device, and/or the like.

A via 112 extends through the one or more intermediate interconnect layers 106 within the logic region 902. In some embodiments, the via 112 vertically extends past top and bottom surfaces of the data storage element 910. In some embodiments, the via 112 vertically extends past the plurality of transistor devices 908 and the data storage element 910.

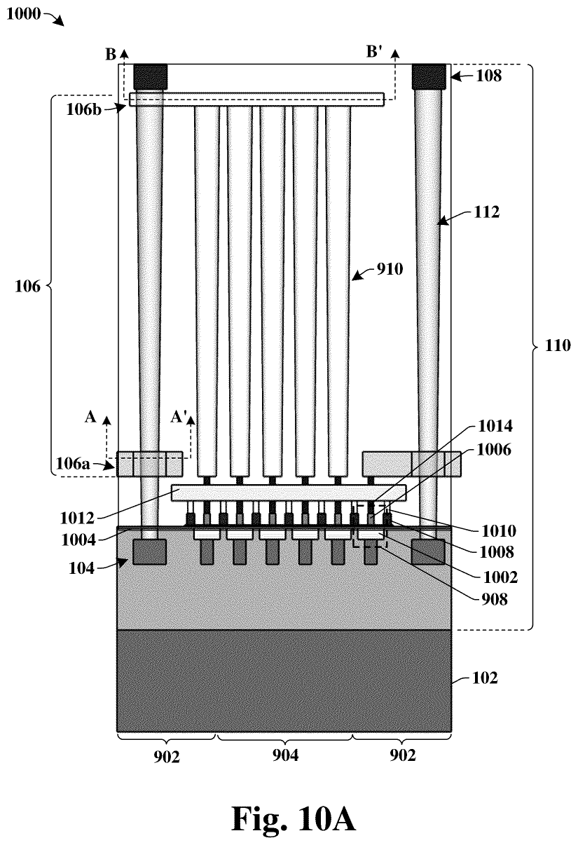

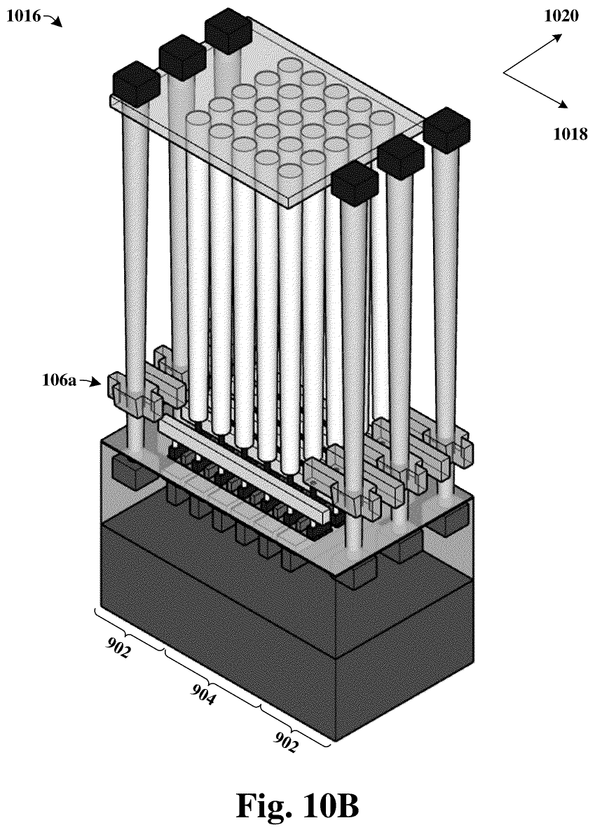

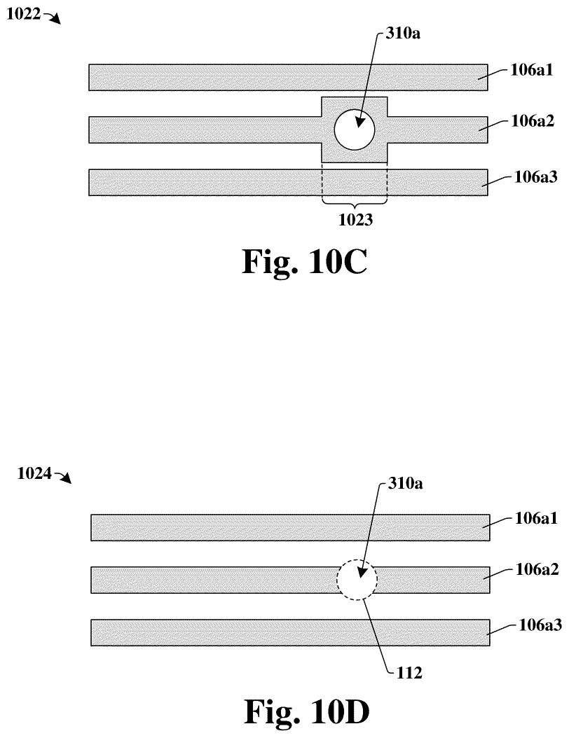

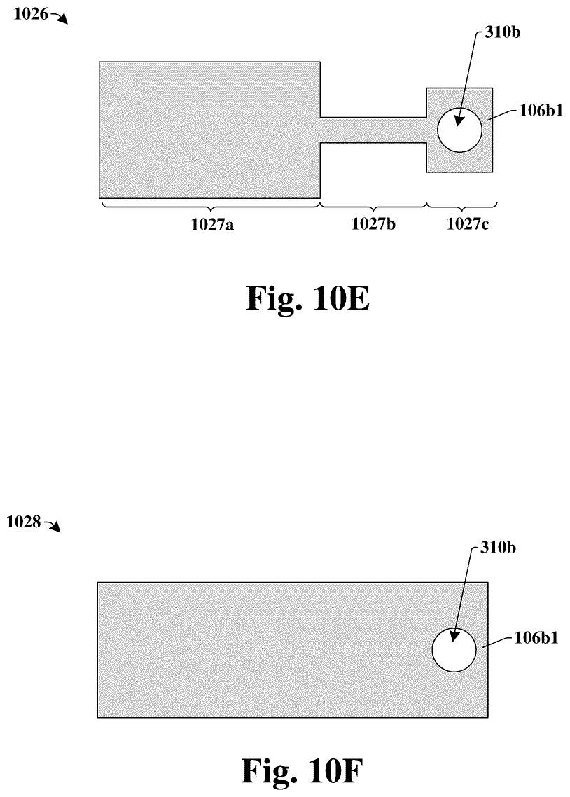

FIG. 10A illustrates a cross-sectional view of some additional embodiments of an integrated chip structure 1000 having via extending over multiple interconnect layers.

The integrated chip structure 1000 includes a substrate 102 having a logic region 902 and a memory region 904. An ILD structure 110 is disposed over the substrate 102 within the logic region 902 and the memory region 904. Within the logic region 902, the ILD structure 110 surrounds a plurality of interconnect layers including a lower interconnect layer 104, one or more intermediate interconnect layers 106, and an upper interconnect layer 108. Within the memory region 904, the ILD structure 110 further surrounds a plurality of memory devices.

The plurality of memory devices include transistor devices 908 coupled to data storage elements 910. The transistor devices 908 respectively include a channel layer 1004 disposed over gate structures 1002 within the lower interconnect layer 104. In some embodiments, the channel layer 1004 may comprise an oxide semiconductor, a high-k dielectric layer, or the like. In some embodiments, the gate structures 1002 may continuously extend past multiple channel layers to act as word-lines. In some embodiments, a gate dielectric (not shown) may separate the gate structure 1002 from the channel layer 1004. Alternating source contacts 1006 and drain contacts 1008 are disposed over the channel layer 1004. Bit-line vias 1010 extend from the drain contacts 1008 to a bit-line 1012 that laterally extends past a plurality of memory device vias 1014 that extend from the source contacts 1006 to the data storage elements 910. During operation, one or more memory control circuits (not shown) may access the plurality of memory devices by applying voltages to select word-lines and/or bit-lines.

In some embodiments, one of the memory device vias 1014 couples the source contacts 1006 to a first intermediate interconnect on a first intermediate interconnect layer 106a. The first intermediate interconnect laterally extends from within the memory region 904 to within the logical region 902 (e.g., to one or more memory control circuits implemented in the logic region 902). In some embodiments, the data storage elements 910 extend from the plurality of memory device vias 1014 to a second intermediate interconnect on a second intermediate interconnect layer 106b. The second intermediate interconnect laterally extends from within the memory region 904 to within the logical region 902 (e.g., to one or more memory control circuits implemented in the logic region 902) on a second intermediate interconnect layer 106b. A via 112 extends through the one or more intermediate interconnect layers 106 within the logic region 902. The via 112 vertically extends past the plurality of transistor devices 908 and the data storage element 910.

FIG. 10B illustrates a three-dimensional view 1016 of the integrated chip structure of FIG. 10B.

As shown in the three-dimensional view 1016, the memory devices are arranged in a memory array extending along a first direction 1018 and along a second direction 1020 that is perpendicular to the first direction 1018. Rows of the memory array (extending along the first direction 1018) are coupled to one of the intermediate interconnect that is on the first intermediate interconnect layer 106a that extends into the logic region 902.

FIG. 10C illustrates a top-view 1022 showing some embodiments of a first intermediate interconnect layer taken along cross-sectional line A-A′ of FIG. 10A.

As shown in top-view 1022, the first intermediate interconnect layer comprises a plurality of first intermediate interconnect segments 106a1-106a3. A first intermediate interconnect segment 106a1 and a third intermediate interconnect segment 106a3 have a same first shape, while a second intermediate interconnect segment 106a2 has a second shape. The first shape is a rectangular shape with a substantially constant width. The second shape includes a transitional region 1023 that includes an aperture 310a through which a via extends.

FIG. 10D illustrates a top-view 1024 showing some alternative embodiments of a first intermediate interconnect layer taken along cross-sectional line A-A′ of FIG. 10A.

As shown in top-view 1024, the first intermediate interconnect layer comprises a plurality of first intermediate interconnect segments 106a1-106a3. The plurality of first intermediate interconnect segments comprise a first intermediate interconnect segment 106a1, a second intermediate interconnect segment 106a2, and a third intermediate interconnect segment 106a3 having a same shape (e.g., a rectangular shape with a substantially constant width). An aperture 310a extends through the second intermediate interconnect segment 106a2. Because a via 112 may have a larger width than the second intermediate interconnect segment 106a2, the aperture 310a may extend between opposing sides of the second intermediate interconnect segment 106a2.

FIG. 10E illustrates a top-view 1026 showing some embodiments of a second intermediate interconnect layer taken along cross-sectional line B-B′ of FIG. 10A.

As illustrated in top-view 1026, the second intermediate interconnect layer comprises a second intermediate interconnect segment 106b1 having a first width within a first part 1027a that is in the memory region and within a third part 1027c that surrounds an aperture 310b through which a via extends. The second intermediate interconnect segment 106b1 has a second width, which is smaller than the first width, within a second part 1027b that is between the first part 1027a and the third part 1027c.

FIG. 10F illustrates a top-view 1028 showing some alternative embodiments of a second intermediate interconnect layer taken along cross-sectional line B-B′ of FIG. 10A.

As illustrated in top-view 1028, the second intermediate interconnect layer comprises a second intermediate interconnect segment 106b1 having a substantially constant width.

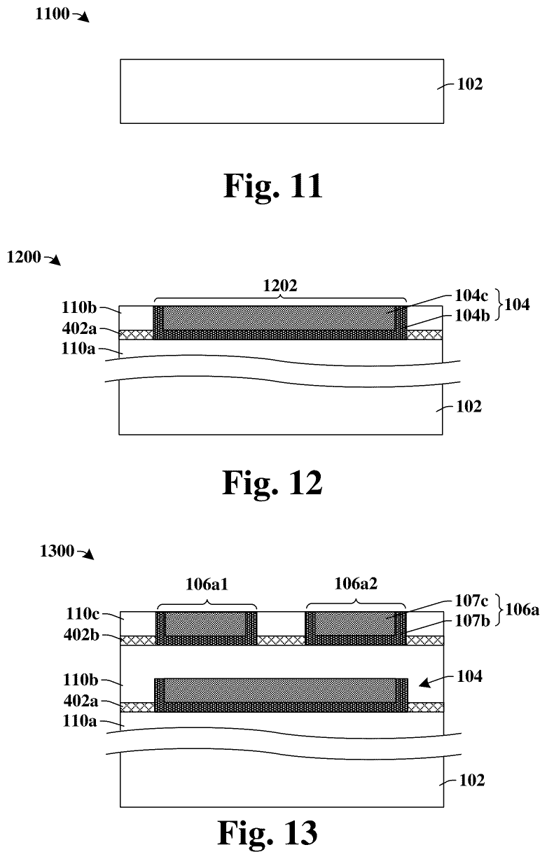

FIGS. 11-19 illustrate cross-sectional views 1100-1900 corresponding to some embodiments of a method of forming an integrated chip structure having a via extending over multiple interconnect layers. Although the structures shown in the cross-sectional views 1100-1900 of FIGS. 11-19 are described with reference to a method, it will be appreciated that the structures shown in the cross-sectional views of FIGS. 11-19 are not limited to the method of formation but rather may stand alone separate of the method.

As shown in cross-sectional view 1100 of FIG. 11, a substrate 102 is provided. In various embodiments, the substrate 102 may be any type of substrate (e.g., silicon, SiGe, SOI, etc.), such as a semiconductor wafer, as well as any other type of semiconductor and/or epitaxial layers, associated therewith.

As shown in cross-sectional view 1200 of FIG. 12, a lower etch stop layer (ESL) 402a is formed over the substrate 102 and a lower inter-level dielectric (ILD) layer 110b is formed over the lower ESL 402a. In some embodiments, the lower ESL 402a and the lower ILD layer 110b may be formed by one or more deposition processes (e.g., a physical vapor deposition (PVD) process, a chemical vapor deposition (CVD) process, a plasma enhanced CVD (PE-CVD) process, and/or the like). In some embodiments, the lower ESL 402a may comprise a nitride, a carbide, and/or the like. In some embodiments, the lower ILD layer 110b may comprise silicon dioxide, carbon doped silicon oxide (SiCOH), phosphosilicate glass (PSG), borophosphosilicate glass (BPSG), borosilicate glass (BSG), fluorosilicate glass (FSG), undoped silicate glass (USG), and/or the like. In some embodiments (not shown), one or more additional ILD layers 110a may be disposed between the lower ESL 402a and the substrate 102.

A lower interconnect layer 104 is formed within the lower ILD layer 110b. In some embodiments, the lower interconnect layer 104 may comprise a lower interconnect formed using a damascene process. The damascene process may include performing a patterning process on the lower ILD layer 110b to form a lower interconnect opening 1202 formed by sidewalls of the lower ILD layer 110b. In some embodiments, the patterning process may comprise a lithography process followed by an etching process that selectively exposes the lower ILD layer 110b to an etchant (e.g., a dry etchant having a fluorine chemistry, a chlorine chemistry, or the like). A lower barrier 104b is formed within the lower interconnect opening 1202. A lower conductive core 104c is formed on the lower barrier 104b and within the lower interconnect opening 1202. A planarization process (e.g., a chemical mechanical planarization (CMP) process) is performed to remove parts of the lower barrier 104b and the lower conductive core 104c that are over the lower ILD layer 110b and to form the lower interconnect layer 104.

After formation of the lower interconnect layer 104, one or more intermediate interconnect layers are formed. FIGS. 12-14 illustrate the formation of three intermediate interconnect layers. While FIGS. 12-14 illustrate the formation of three intermediate interconnect layers, it will be appreciated that in various embodiments, more or less than three intermediate interconnect layers may be formed onto the lower interconnect layer.

As shown in cross-sectional view 1300 of FIG. 13, a thickness of the lower ILD layer is increased to cover the lower interconnect layer 104. A first intermediate ESL 402b is then formed over the lower ILD layer 110b and a first intermediate ILD layer 110c is formed over the first intermediate ESL 402b. A first intermediate interconnect layer 106a is formed within the first intermediate ILD layer 110c. The first intermediate interconnect layer 106a may comprise a plurality of intermediate interconnect segments 106a1-106a2. The various embodiments, the plurality of intermediate interconnect segments 106a1-106a2 may comprise separate interconnects or be part of a single interconnect. In some embodiments, the first intermediate ESL 402b and the first intermediate ILD layer 110c may be respectively formed by one or more deposition processes (e.g., a PVD process, a CVD process, a PE-CVD process, and/or the like). In some embodiments, the first intermediate interconnect layer 106a may be formed by a damascene process that forms an intermediate barrier 107b and an intermediate conductive core 107c within an intermediate interconnect opening.

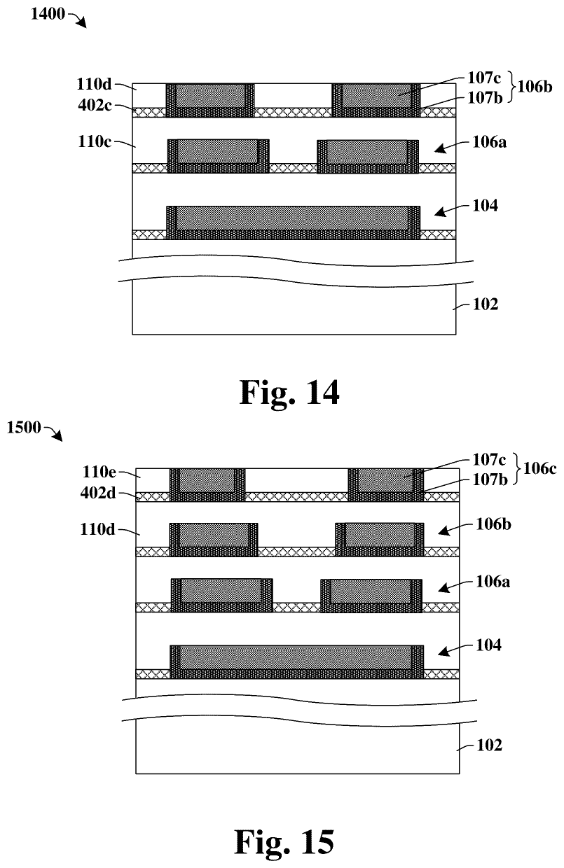

As shown in cross-sectional view 1400 of FIG. 14, a thickness of the first intermediate ILD layer 110c is increased to cover the first intermediate interconnect layer 106a. A second intermediate ESL 402c is then formed over the first intermediate ILD layer 110c and a second intermediate ILD layer 110d is formed over the second intermediate ESL 402c. A second intermediate interconnect layer 106b is formed within the second intermediate ILD layer 110d. In some embodiments, the second intermediate ESL 402c and the second intermediate ILD layer 110d may be respectively formed by one or more deposition processes (e.g., a PVD process, a CVD process, a PE-CVD process, and/or the like). In some embodiments, the second intermediate interconnect layer 106b may be formed by a damascene process.

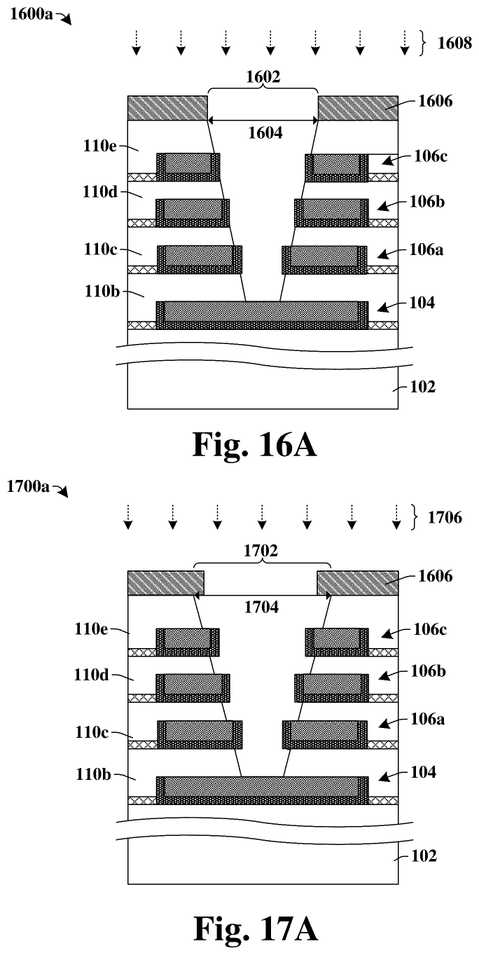

As shown in cross-sectional view 1500 of FIG. 15, a thickness of the second intermediate ILD layer 110d is increased to cover the second intermediate interconnect layer 106b. A third intermediate ESL 402d is then formed over the second intermediate ILD layer 110d and a third intermediate ILD layer 110e is formed over the third intermediate ESL 402d. A third intermediate interconnect layer 106c is formed within the third intermediate ILD layer 110e. In some embodiments, the third intermediate ESL 402d and the third intermediate ILD layer 110e may be respectively formed by one or more deposition processes (e.g., a PVD process, a CVD process, a PE-CVD process, and/or the like). In some embodiments, the third intermediate interconnect layer 106e may be formed by a damascene process.

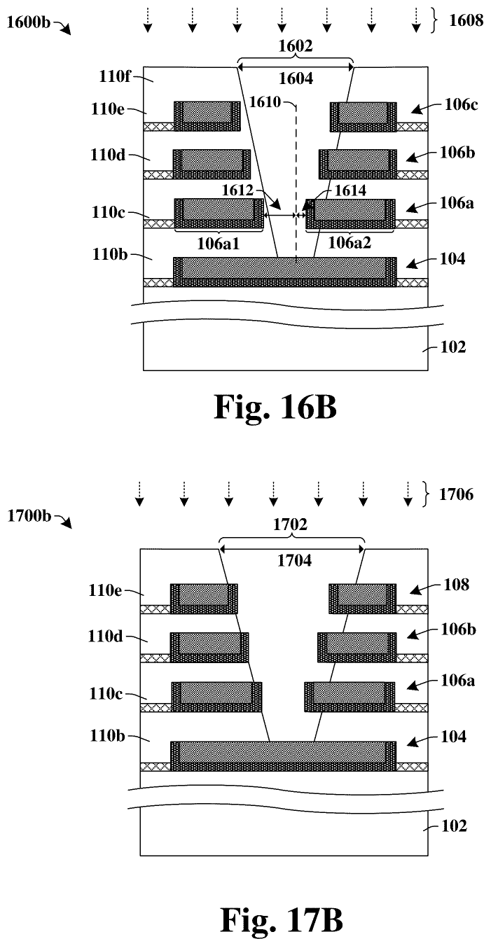

FIGS. 16A and 17A illustrate some embodiments showing the formation of a via opening.

As shown in cross-sectional view 1600a of FIG. 16A, a thickness of the third intermediate ILD layer 110e is increased to cover the third intermediate interconnect layer 106c. A patterning process is subsequently performed on the intermediate ILD layers 110c-110e. The patterning process removes parts of the intermediate ILD layers 110c-110e to form an opening 1602 between sidewalls of the intermediate interconnect layers 106a-106c that face one another. In some embodiments, the opening 1602 may have a first width 1604. In some embodiments, the patterning process may comprise an etching process (e.g., an anisotropic etching process) that selectively exposes the intermediate ILD layers 110c-110e to an etchant 1608 according to a mask 1606 formed over the intermediate ILD layers 110c-110e. In some embodiments, the etchant 1608 may comprise and/or be a dry etchant (e.g., having a fluorine or chlorine based etching chemistry).

As shown in cross-sectional view 1700a of FIG. 17A, a lateral etching process is performed on the intermediate ILD layers 110c-110e to increase a width of the opening (e.g., 1602) and to form a via opening 1702 having a second width 1704 that is larger than the first width (e.g., 1604 of FIG. 16) of the opening. The via opening 1702 exposes upper surfaces and lower surfaces of the one or more intermediate interconnect layers 106a-106c. In some embodiments, the lateral etching process may comprise an etching process that selectively exposes the intermediate ILD layers 110c-110e to a wet etchant 1706. In some embodiments, the wet etchant 1706 may comprise and/or be potassium hydroxide (KOH), hydrofluoric acid (HF), piranha solutions, and/or the like.

FIGS. 16B and 17B illustrate some alternative embodiments showing the formation of a via opening.

As shown in cross-sectional view 1600b of FIG. 16B, a patterning process is performed to remove parts of the intermediate ILD layers 110c-110e to form an opening 1602 that is off-centered from the intermediate interconnect layers 106a-106c. For example, a center of the opening (shown along line 1610) may be separated from a first intermediate interconnect segments 106a1 by a first distance 1612 and be further separated from a second intermediate interconnect segment 106a2 by a second distance 1614 that is different than the first distance 1612. In some embodiments (not shown), the opening 1602 may expose a sidewall of the first intermediate interconnect segments 106a1 while being separated from a sidewall of the second intermediate interconnect segment 106a2 by an ILD layer.

As shown in cross-sectional view 1700b of FIG. 17B, a lateral etching process is performed on the intermediate ILD layers 110c-110e to increase a width of the opening and to form a via opening 1702. The via opening 1702 exposes upper surfaces and lower surfaces of the one or more intermediate interconnect layers 106a-106c.

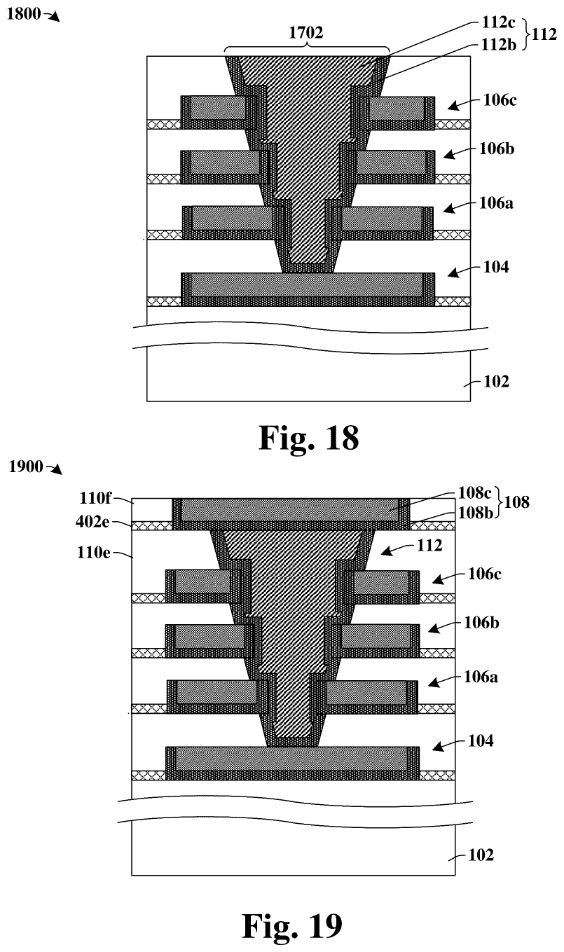

As shown in cross-sectional view 1800 of FIG. 18, a via barrier 112b is formed within the via opening 1702. A via conductive core 112c is formed on the via barrier 112b and within the via opening 1702. A planarization process (e.g., a chemical mechanical planarization (CMP) process) is performed to remove parts of the via barrier 112b and the via conductive core 112c that are over the intermediate ILD layers 110c-110e and to form the via 112.

As shown in cross-sectional view 1900 of FIG. 19, an upper ESL 402e is formed over the third intermediate ILD layer 110e and an upper ILD layer 110f is formed over the upper ESL 402e. An upper interconnect layer 108 is formed within the upper ILD layer 110f. In some embodiments, the upper ESL 402e and the upper ILD layer 110f may be respectively formed by one or more deposition processes (e.g., a PVD process, a CVD process, a PE-CVD process, and/or the like). In some embodiments, the upper interconnect layer 108 may be formed by a damascene process that forms an upper barrier 108b and an upper conductive core 108c within an upper interconnect opening.

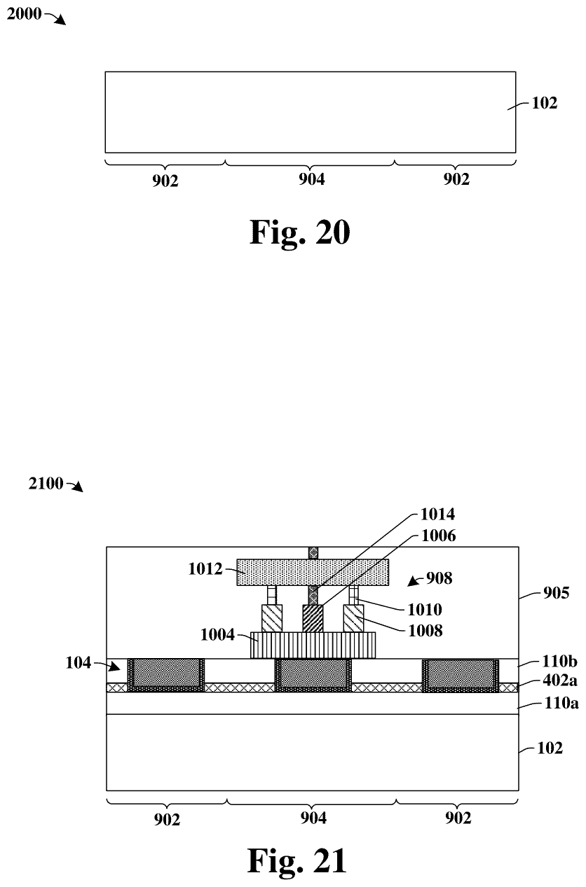

FIGS. 20-29 illustrate cross-sectional views 2000-2900 corresponding to some additional embodiments to a method of forming an integrated chip structure having a via extending over multiple interconnect layers. Although the structures shown in the cross-sectional views 2000-2900 of FIGS. 20-29 are described with reference to a method, it will be appreciated that the structures shown in the cross-sectional views 2000-2900 of FIGS. 20-29 are not limited to the method of formation but rather may stand alone separate of the method.

As shown in cross-sectional view 2000 of FIG. 20, a substrate 102 is provided. In various embodiments, the substrate 102 may be any type of substrate (e.g., silicon, SiGe, SOI, etc.), such as a semiconductor wafer, as well as any other type of semiconductor and/or epitaxial layers, associated therewith. The substrate comprises a logic region 902 and a memory region 904.

As shown in cross-sectional view 2100 of FIG. 21, a lower etch stop layer (ESL) 402a is formed over the substrate 102 and a lower inter-level dielectric (ILD) layer 110b is formed over the lower ESL 402a. In some embodiments, the lower ESL 402a and the lower ILD layer 110b may be formed by one or more deposition processes (e.g., a PVD process, a CVD process, a PE-CVD process, and/or the like). A lower interconnect layer 104 is formed within the lower ILD layer 110b. In some embodiments, the lower interconnect layer 104 may be formed using a damascene process.

After formation of the lower interconnect layer 104, one or more transistor devices 908 are formed within a device ILD structure 905. The one or more transistor devices 908 may be formed to comprise a channel layer 1004 formed on a gate dielectric (not shown) over a gate structure within the lower interconnect layer 104. Alternating source contacts 1006 and drain contacts 1008 are formed over the channel layer 1004. Bit-line vias 1010 are formed on the drain contacts 1008 and a bit-line 1012 is formed on the bit-line vias 1010. A plurality of memory device vias 1014 are subsequently formed on the source contacts 1006.

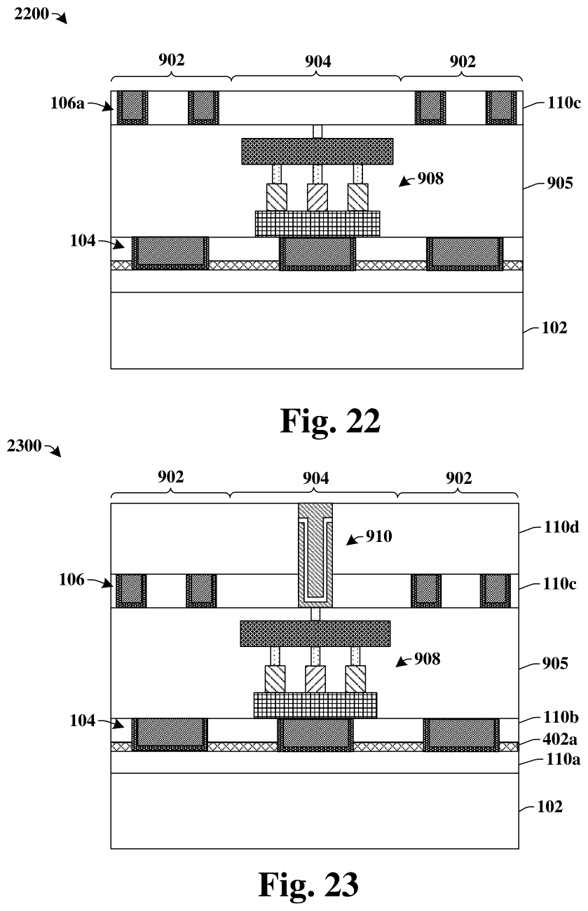

As shown in cross-sectional view 2200 of FIG. 22, a first intermediate interconnect layer 106a is formed within a first intermediate ILD layer 110c formed over the device ILD structure 905. In some embodiments, the first intermediate interconnect layer 106a may be formed using a damascene process.

As shown in cross-sectional view 2300 of FIG. 23, one or more data storage elements 910 are formed within the first intermediate ILD layer 110c and a second intermediate ILD layer 110d formed over the first intermediate ILD layer 110c.

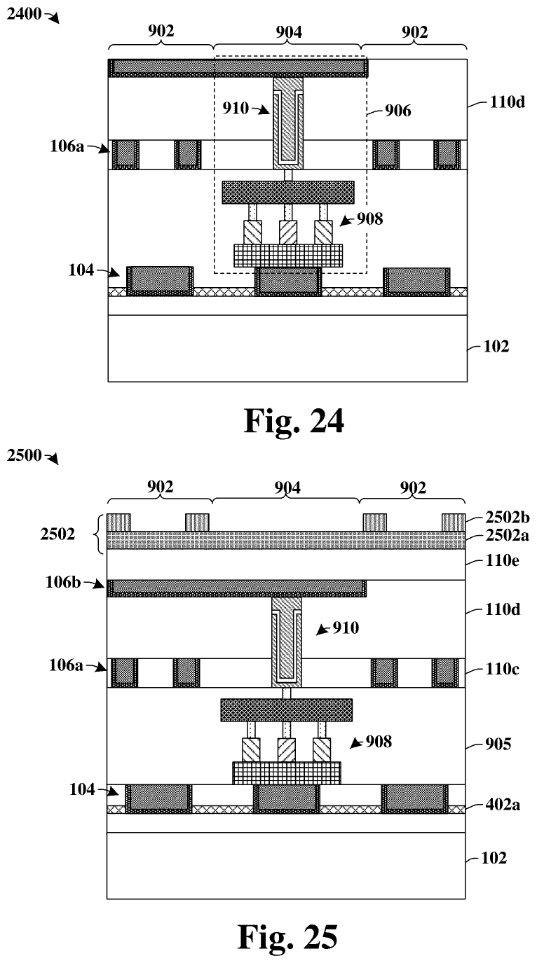

As shown in cross-sectional view 2400 of FIG. 24, a thickness of the second intermediate ILD layer 110d is increased to cover the one or more data storage elements 910. A second intermediate interconnect layer 106b is subsequently formed within the second intermediate ILD layer 110d and on the one or more data storage elements 910.

As shown in cross-sectional view 2500 of FIG. 25, a third intermediate ILD layer 110e is formed over the second intermediate ILD layer 110d. A masking structure 2502 is then formed over the third intermediate ILD layer 110e. In some embodiments, the masking structure 2502 may comprise a hard mask layer 2502a and a photoresist layer 2502b disposed over the hard mask layer 2502a. In some embodiments, the hard mask layer 2502a may comprise a metal (e.g., titanium, titanium nitride, tantalum, etc.), and oxide (e.g., silicon oxynitride), or the like.

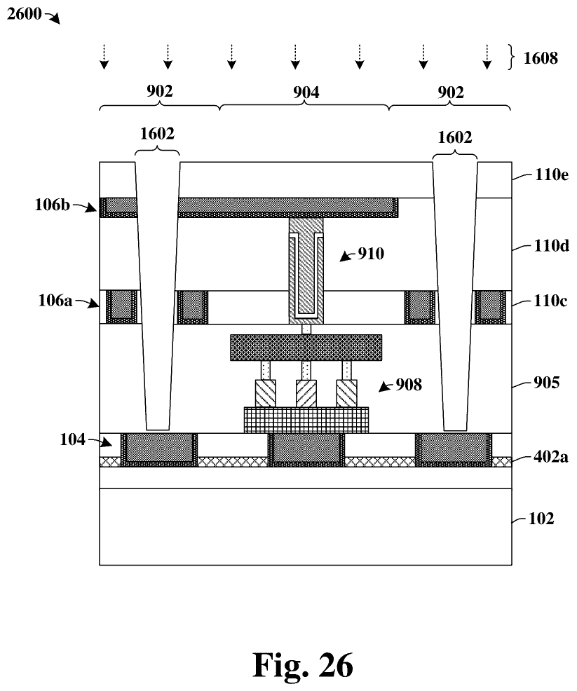

As shown in cross-sectional view 2600 of FIG. 26, a patterning process is subsequently performed on the intermediate ILD layers 110c-110e. The patterning process removes parts of the intermediate ILD layers 110c-110e to form an opening 1602 between sidewalls of the intermediate interconnect layers 106a-106c that face one another. In some embodiments, the opening 1602 may have a first width 1604. In some embodiments, the patterning process may comprise an etching process (e.g., an anisotropic etching process) that selectively exposes the intermediate ILD layers 110c-110e to an etchant 1608 according to the masking structure (e.g., 2502 of FIG. 25).

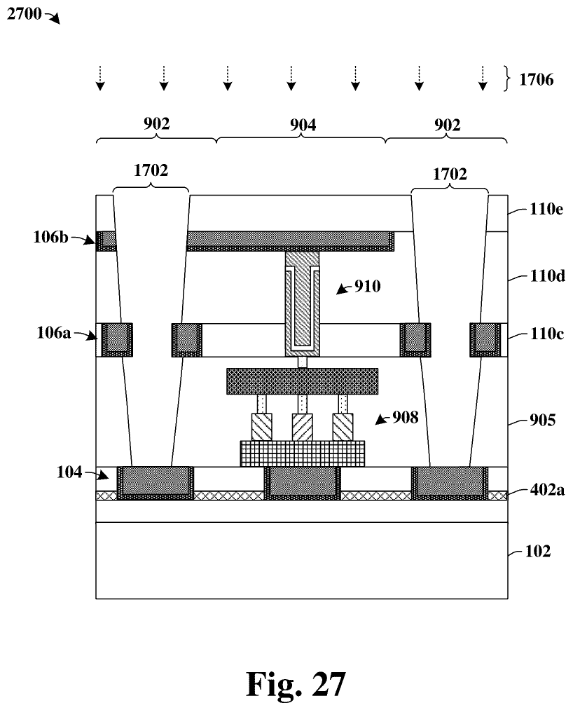

As shown in cross-sectional view 2700 of FIG. 27, a lateral etching process is performed on the intermediate ILD layers 110c-110e to increase a width of the opening (e.g., 1602) and to form a via opening 1702. The via opening 1702 exposes upper surfaces and lower surfaces of the one or more intermediate interconnect layers 106a-106c. In some embodiments, the lateral etching process may comprise an etching process that selectively exposes the intermediate ILD layers 110c-110e to a wet etchant 1706.

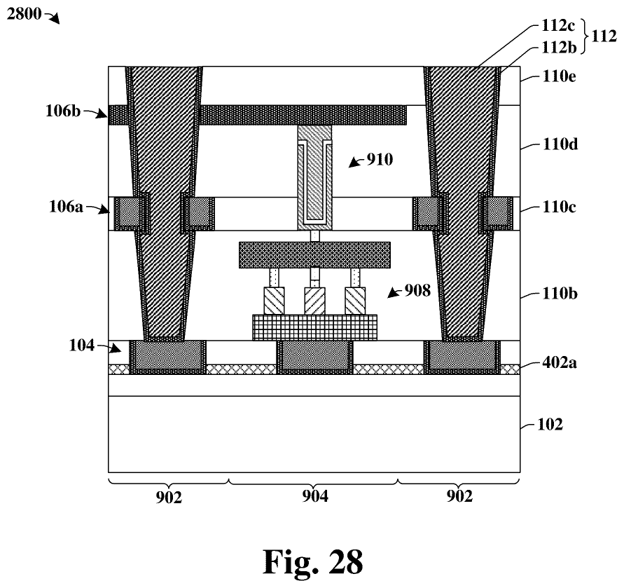

As shown in cross-sectional view 2800 of FIG. 28, a via barrier 112b is formed within the via opening 1702. A via conductive core 112c is formed on the via barrier 112b and within the via opening 1702. A planarization process (e.g., a chemical mechanical planarization (CMP) process) is performed to remove parts of the via barrier 112b and the via conductive core 112c that are over the intermediate ILD layers 110c-110e and to form the via 112.

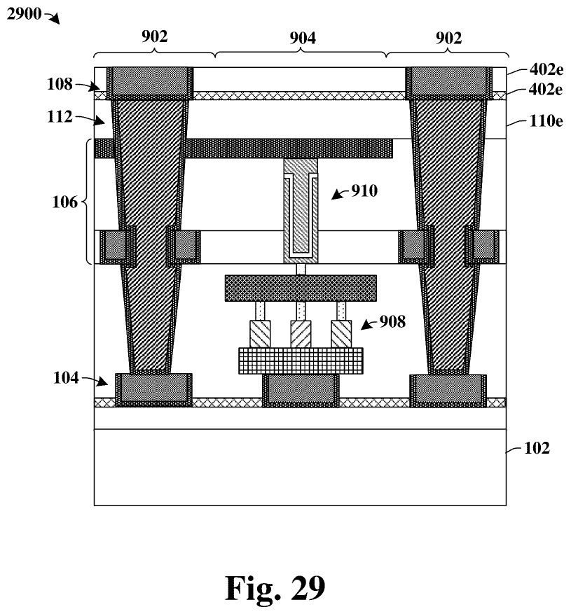

As shown in cross-sectional view 2900 of FIG. 29, an upper ESL 402e is formed over the third intermediate ILD layer 110e and an upper ILD layer 110f is formed over the upper ESL 402e. An upper interconnect layer 108 is formed within the upper ILD layer 110f. In some embodiments, the upper ESL 402e and the upper ILD layer 110f may be respectively formed by one or more deposition processes (e.g., a PVD process, a CVD process, a PE-CVD process, and/or the like). In some embodiments, the upper interconnect layer 108 may be formed by a damascene process.

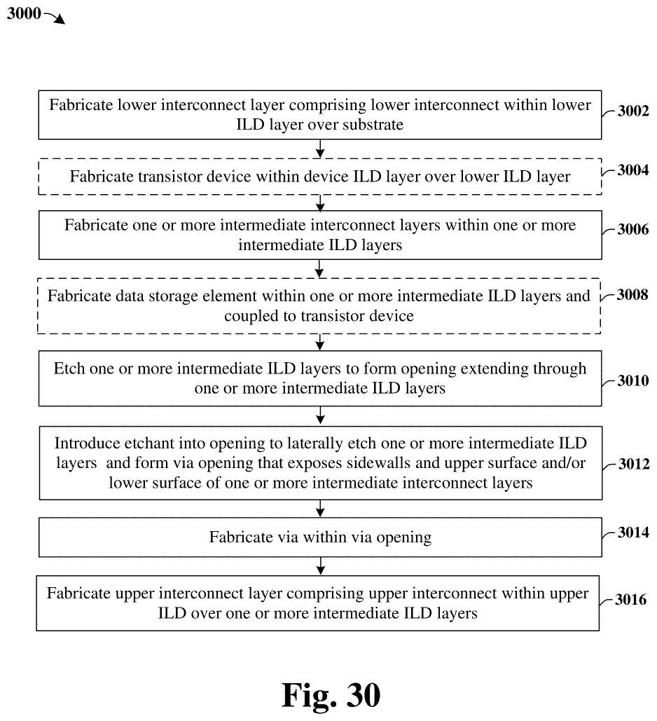

FIG. 30 illustrates a flow diagram of some embodiments of a method 3000 of forming an integrated chip memory structure having access transistor with an asymmetric source/drain design.

While method 3000 is illustrated and described herein as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At act 3002, a lower interconnect layer comprising a lower interconnect is fabricated within a lower ILD layer over substrate. FIG. 12 illustrates a cross-sectional view 1300 of some embodiments corresponding to act 3002. FIG. 21 illustrates a cross-sectional view 2100 of some additional embodiments corresponding to act 3002.

At act 3004, a transistor device may be fabricated within a device ILD layer formed over the lower ILD layer, in some embodiments. FIG. 22 illustrates a cross-sectional view 2200 of some embodiments corresponding to act 3004.

At act 3006, one or more intermediate interconnect layers are fabricated within one or more intermediate ILD layers over the lower ILD layer. FIGS. 13-15 illustrate cross-sectional views 1300-1500 of some embodiments corresponding to act 3006. FIGS. 22 and 24 illustrate cross-sectional views 2200 and 2400 of some additional embodiments corresponding to act 3006.

At act 3008, a data storage element may be fabricated within the one or more intermediate ILD layers and coupled to the transistor device, in some embodiments. FIGS. 21 and 23 illustrate cross-sectional views 2100 and 2300 of some additional embodiments corresponding to act 3008.

At act 3010, the one or more intermediate ILD layers are etched to form an opening extending through the one or more intermediate ILD layers. FIG. 15A illustrates a cross-sectional view 1500a of some embodiments corresponding to act 3010. FIG. 15B illustrates a cross-sectional view 1500b of some additional embodiments corresponding to act 3010. FIG. 26 illustrates a cross-sectional view 2600 of some additional embodiments corresponding to act 3010.

At act 3012, an etchant is introduced into the opening to laterally etch the one or more intermediate ILD layers and form a via opening that exposes sidewalls and upper surface and/or lower surface of one or more intermediate interconnect layers. FIG. 16A illustrates a cross-sectional view 1600a of some embodiments corresponding to act 3012. FIG. 16B illustrates a cross-sectional view 1600b of some additional embodiments corresponding to act 3012. FIG. 27 illustrates a cross-sectional view 2700 of some additional embodiments corresponding to act 3012.

At act 3014, a via is fabricated within the via opening. FIG. 18 illustrates a cross-sectional view 1800 of some embodiments corresponding to act 3014. FIG. 28 illustrates a cross-sectional view 2800 of some additional embodiments corresponding to act 3014.

At act 3016, an upper interconnect layer comprising upper interconnect is fabricated within an upper ILD formed over one or more intermediate ILD layers. FIG. 19 illustrates a cross-sectional view 1900 of some embodiments corresponding to act 3016. FIG. 29 illustrates a cross-sectional view 2900 of some additional embodiments corresponding to act 3016.

Accordingly, in some embodiments, the present disclosure relates to a method of forming an integrated chip structure comprising a via that vertically extends through an intermediate interconnect layer to electrically couple an underlying lower interconnect to an overlying upper interconnect.

In some embodiments, the present disclosure relates to an integrated chip. The integrated chip includes a lower interconnect layer disposed within a lower inter-level dielectric (ILD) layer on a substrate; an upper interconnect layer disposed within an upper ILD layer on the substrate; one or more intermediate ILD layers disposed between the lower ILD layer and the upper ILD layer; one or more intermediate interconnect layers disposed within the one or more intermediate ILD layers; and a via extending between the lower interconnect layer and the upper interconnect layer, the via laterally contacting one or more sidewalls of the one or more intermediate interconnect layers. In some embodiments, the one or more intermediate interconnect layers include a first intermediate interconnect segment contacting a first sidewall of the via and a second intermediate interconnect segment contacting an opposing second sidewall of the via, as viewed in a cross-sectional view. In some embodiments, the via laterally overlaps the first intermediate interconnect segment by a first non-zero distance and the second intermediate interconnect segment by a second non-zero distance. In some embodiments, the first non-zero distance is larger than the second non-zero distance. In some embodiments, the one or more intermediate interconnect layers include a first intermediate interconnect layer and a second intermediate interconnect layer directly over the first intermediate interconnect layer; and the via includes a protrusion laterally extending outward from a sidewall of the via to directly between the first intermediate interconnect layer and the second intermediate interconnect layer. In some embodiments, the via extends to directly over an upper surface of the one or more intermediate interconnect layers. In some embodiments, the integrated chip further includes a lower via disposed below the lower interconnect layer, the via having a larger width than the lower via. In some embodiments, the via both laterally and vertically contacts the one or more intermediate interconnect layers. In some embodiments, the integrated chip further includes a transistor device disposed along a front-side of the substrate; a plurality of front-side interconnect layers disposed within a front-side ILD structure arranged on the front-side of the substrate, the lower interconnect layer being arranged between the plurality of front-side interconnect layers and the front-side of the substrate; and the one or more intermediate interconnect layers and the upper interconnect layer being disposed on a back-side of the substrate opposing the front-side, the via extending through the substrate. In some embodiments, the integrated chip further includes a transistor device disposed within a device ILD layer arranged between the one or more intermediate ILD layers; a data storage element disposed within the one or more intermediate ILD layers and electrically coupled to the transistor device, the transistor device being between the data storage element and the lower ILD layer; and the via vertically extending past top and bottom surfaces of the data storage element.

In other embodiments, the present disclosure relates to method of forming an integrated chip. The method includes forming a lower interconnect within a lower ILD layer formed on a substrate; forming one or more intermediate interconnects within one or more intermediate ILD layers formed on the substrate; etching the one or more intermediate ILD layers to form an opening extending through the one or more intermediate ILD layers; introducing an etchant into the opening to etch the one or more intermediate ILD layers to form a via opening, the via opening exposing an upper surface of the lower interconnect and a sidewall of the one or more intermediate interconnects; and forming a via comprising a conductive material within the via opening. In some embodiments, the method further includes forming an upper interconnect within an upper ILD separated from the substrate by the one or more intermediate ILD layers, the upper interconnect contacting the upper surface of the via. In some embodiments, the via wraps around the upper surface and a lower surface of the one or more intermediate interconnects. In some embodiments, the one or more intermediate interconnects include a first intermediate interconnect having an intermediate conductive core laterally surrounded by an intermediate barrier; and the via includes a via conductive core laterally surrounded by a via barrier, the via barrier contacting the intermediate barrier along an interface. In some embodiments, the one or more intermediate interconnects protrude outward from within recesses in a side of the via to laterally outside of the via.

In yet other embodiments, the present disclosure relates to a method of forming an integrated chip. The method includes fabricating a lower interconnect layer within a lower ILD layer formed on a substrate; fabricating a first intermediate interconnect segment and a second intermediate interconnect segment within an intermediate ILD layer formed over the lower ILD layer; etching an intermediate ILD layer to form an opening extending through the intermediate ILD layer and between the first intermediate interconnect segment and the second intermediate interconnect segment; increasing a width of the opening to form a via opening, the via opening exposing an upper surface of the lower interconnect layer and sidewalls of the first intermediate interconnect segment and the second intermediate interconnect segment; and depositing a conductive material within the via opening. In some embodiments, the via opening exposes upper surfaces and lower surfaces of the first intermediate interconnect segment and the second intermediate interconnect segment. In some embodiments, the first intermediate interconnect segment and the second intermediate interconnect segment are part of an intermediate interconnect that wraps are the via opening in a closed and unbroken loop. In some embodiments, the first intermediate interconnect segment is a first intermediate interconnect and the second intermediate interconnect segment is a second intermediate interconnect, the first intermediate interconnect and the second intermediate interconnect having outermost sidewalls that face one another and that are separated from one another by the via opening. In some embodiments, the first intermediate interconnect segment includes an intermediate conductive core laterally surrounded by an intermediate barrier; and the via includes a via conductive core laterally surrounded by a via barrier, the via barrier contacting the intermediate barrier along an interface.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated chip, comprising:
a lower interconnect layer disposed within a lower inter-level dielectric (ILD) layer on a substrate;
an upper interconnect layer disposed within an upper ILD layer on the substrate;
one or more intermediate ILD layers disposed between the lower ILD layer and the upper ILD layer;
one or more intermediate interconnect layers disposed within the one or more intermediate ILD layers; and
a via extending between the lower interconnect layer and the upper interconnect layer, wherein the via laterally contacts one or more sidewalls of the one or more intermediate interconnect layers.

2. The integrated chip of claim 1, wherein the one or more intermediate interconnect layers include a first intermediate interconnect segment contacting a first sidewall of the via and a second intermediate interconnect segment contacting an opposing second sidewall of the via, as viewed in a cross-sectional view.

3. The integrated chip of claim 2, wherein the via laterally overlaps the first intermediate interconnect segment by a first non-zero distance and the second intermediate interconnect segment by a second non-zero distance that is different than the first non-zero distance.

4. The integrated chip of claim 1, further comprising:
a first etch stop layer arranged between the one or more intermediate ILD layers and the upper ILD layer; and
a second etch stop layer arranged between the one or more intermediate ILD layers and the lower ILD layer, wherein the via extends through the first etch stop layer and the second etch stop layer.

5. The integrated chip of claim 1,
wherein the one or more intermediate interconnect layers include a first intermediate interconnect layer and a second intermediate interconnect layer directly over the first intermediate interconnect layer; and
wherein the via comprises a protrusion laterally extending outward from a sidewall of the via to directly between the first intermediate interconnect layer and the second intermediate interconnect layer.

6. The integrated chip of claim 1, wherein the via extends to directly over an upper surface of the one or more intermediate interconnect layers.

7. The integrated chip of claim 1, further comprising:
a lower via disposed below the lower interconnect layer, wherein the via has a larger width than the lower via.

8. The integrated chip of claim 1, wherein the via both laterally and vertically contacts the one or more intermediate interconnect layers.

9. The integrated chip of claim 1, further comprising:
a transistor device disposed along a front-side of the substrate;
a plurality of front-side interconnect layers disposed within a front-side ILD structure arranged on the front-side of the substrate, wherein the lower interconnect layer is arranged between the plurality of front-side interconnect layers and the front-side of the substrate; and
wherein the one or more intermediate interconnect layers and the upper interconnect layer are disposed on a back-side of the substrate opposing the front-side, the via extending through the substrate.

10. The integrated chip of claim 1, further comprising:
a transistor device disposed within a device ILD layer arranged between the one or more intermediate ILD layers;
a data storage element disposed within the one or more intermediate ILD layers and electrically coupled to the transistor device, the transistor device being between the data storage element and the lower ILD layer; and
wherein the via vertically extends past top and bottom surfaces of the data storage element.

11. A method of forming an integrated chip, comprising:
forming a lower interconnect within a lower ILD layer formed on a substrate;
forming one or more intermediate interconnects within one or more intermediate ILD layers formed on the substrate;
etching the one or more intermediate ILD layers to form an opening extending through the one or more intermediate ILD layers;
introducing an etchant into the opening to etch the one or more intermediate ILD layers to form a via opening, the via opening exposing an upper surface of the lower interconnect and a sidewall of the one or more intermediate interconnects; and
forming a via comprising a conductive material within the via opening.

12. The method of claim 11, further comprising:
forming an upper interconnect within an upper ILD separated from the substrate by the one or more intermediate ILD layers, the upper interconnect contacting the upper surface of the via.

13. The method of claim 11, wherein the via wraps around the upper surface and a lower surface of the one or more intermediate interconnects.

14. The method of claim 11,
wherein the one or more intermediate interconnects comprise a first intermediate interconnect having an intermediate conductive core laterally surrounded by an intermediate barrier; and
wherein the via comprises a via conductive core laterally surrounded by a via barrier, the via barrier contacting the intermediate barrier along an interface.

15. The method of claim 11, wherein the one or more intermediate interconnects protrude outward from within recesses in a side of the via to laterally outside of the via.

16. A method of forming an integrated chip, comprising:
fabricating a lower interconnect layer within a lower ILD layer formed on a substrate;
fabricating a first intermediate interconnect segment and a second intermediate interconnect segment within an intermediate ILD layer formed over the lower ILD layer;
etching the intermediate ILD layer to form an opening extending through the intermediate ILD layer and between the first intermediate interconnect segment and the second intermediate interconnect segment;
increasing a width of the opening to form a via opening, the via opening exposing an upper surface of the lower interconnect layer and sidewalls of the first intermediate interconnect segment and the second intermediate interconnect segment; and
depositing a conductive material within the via opening.

17. The method of claim 16, wherein the via opening exposes upper surfaces and lower surfaces of the first intermediate interconnect segment and the second intermediate interconnect segment.

18. The method of claim 16, wherein the first intermediate interconnect segment and the second intermediate interconnect segment are part of an intermediate interconnect that wraps are the via opening in a closed and unbroken loop.

19. The method of claim 16, wherein the first intermediate interconnect segment is a first intermediate interconnect and the second intermediate interconnect segment is a second intermediate interconnect, the first intermediate interconnect and the second intermediate interconnect having outermost sidewalls that face one another and that are separated from one another by the via opening.

20. The method of claim 16,
wherein the first intermediate interconnect segment comprises an intermediate conductive core laterally surrounded by an intermediate barrier; and
wherein the via comprises a via conductive core laterally surrounded by a via barrier, the via barrier contacting the intermediate barrier along an interface.
